(19) United States
(12) Patent Application Publication
(10) Pub. No.: US 2003/0235089 A1
(43) Pub. Date: Dec. 25, 2003

(54) Memory array with diagonal bitlines

(76) Inventors: Gerhard Mueller, Meitingen (DE); Toshiaki Kirihata, Poughkeepsie, NY (US)

Correspondence Address: SLATER & MATSIL, L.L.P., 17950 PRESTON RD, SUITE 1000, DALLAS, TX, 75252-5793, US

(21) Appl. No.: 10/114,078

(22) Filed: Apr. 2, 2002

(51) Int. Cl. G11C 29/00

(52) U.S. Cl. 365/200

(57) ABSTRACT

An improved memory array having adjacent banks with diagonal bitlines is disclosed. The memory banks include respective memory blocks which are adjacent to each other. The memory blocks comprises diagonal bitlines and twist regions which change the directions of the diagonal bitlines, forming zigzagged sides along the general direction of the bitlines. The bitlines of the adjacent blocks run in the same direction in order to reduce unused area caused by the zigzagged sides of the memory blocks.

### FIELD OF THE INVENTION

The present invention generally relates to integrated circuits. More particularly, the present invention relates to memory integrated circuits.

### BACKGROUND OF THE INVENTION

CMOS technology has evolved at such a brisk pace that the computer market has rapidly opened to a wide range of consumers. Today multi-media computers require preferably 128 MB or beyond, which increases the relative cost of the memories within the computer. In the near future, 512 MB or 1 GB computers will become commonplace, which suggests a potentially strong demand for 256 Mb DRAMs (Dynamic Random Access Memory) and beyond. Despite the huge size of the memory arrays and the lithographic difficulties that ensue, it is even more important to reduce a chip size by improving the cell efficiency defined by the cell area to chip size ratio. It is very important to design the memory array efficiently to improve the cell efficiency (cell area to chip size ratio).

FIG. 1 shows a memory array 101 of an integrated circuit (IC). The memory blocks 130a and 130b comprise a plurality of memory cells 132. They are arranged in a matrix, and supported by wordlines (WLs) in the row direction and bitlines (BLs) in the column direction. This example assumes a dynamic random access memory cell 132 having a transistor and capacitor. However, the invention is not limited only for this case. A plurality of the wordline drivers 140a and 140b activates or selects a WL, reading the data from the memory cells 132 to the BLs. Sense amplifiers (not shown) are coupled to the BLs, amplifying the data signals. A column decoder (not shown) then selects a column to transfer the data bit on the corresponding BL.

Typically, the memory array includes a plurality of sub-arrays or banks. As shown, the memory array comprises first and second banks 110a and 110b. As used herein, a bank (e.g. 110a or 110b) includes a block of memory cells (e.g. 130a or 130b) associated with a respective wordline driver block containing a plurality of wordline drivers (e.g. 140a or 140b). Conventionally, the banks 110a and 110b are arranged as mirror images of each other (i.e. flipped). For example, the first bank supported by wordline drivers 140a is located on the left side of the memory block 130a while the second bank supported by wordline drivers 140b is located on the right side of the memory block 130b. One example of the mirrored subarray architecture is disclosed in Toshiaki Kirihata et. al, “A 220 mm, Four and Eight-Bank, 256 Mb SDRAM with Single-Sided Stitched WL architecture,” IEEE Journal of Solid-State Circuits, Vol.33, No.11, November 1998, pp. 1711-1719.

For the gigabit generation and beyond, a multi-level bitline architecture had been proposed. FIG. 2 shows a multi-level bitline architecture. The memory block 230 comprises a plurality of memory cells 231 arranged in a matrix. They are supported by wordlines (WLs) in the row direction and vertically twisted bitlines (BLs) in the column direction.

As shown in FIG. 2, bitlines 232 and 233 of a bitline pair (bitline true and bitline complement) use first metal (M1) and second metal (M2) levels in a multi level architecture. Memory cells 231 are selected or activated by the wordline driver block 220, similar to FIG. 1. Data bits are read from the memory cells and transmitted to the bitline on the lower level M1 (e.g. memory cell 231 is coupled to bitline 232 at segment 232b). To enable both bitlines to be coupled to memory cells, vertical twists (e.g. 234) are provided to shift the bitlines from one level (M1) to the other (M2). For example, vertical twist 234 divides the bitlines into segments 232a, 232b, 233a and 233b. This results in vertically folded bitlines for differential sensing.

FIG. 3 shows a memory block 330 with a multi-level bitline architecture having vertical twists as described in FIG. 2. As shown, the memory block includes memory cells (e.g. 331) interconnected by wordlines (WLs) in a row direction and bitlines (BL pairs) in a column direction. Diagonal bitlines (i.e. non-orthogonal to the wordlines) allow more space for the twist regions 334, making it easier to lay out the vertically twisted bitlines with small area penalty. The bitlines change direction in twist regions 334 of the array, resulting in the sides of the memory array to run in a zigzagged fashion in the general direction of the bitlines. Diagonal bitlines are described in, for example, the patent application titled “Reduced Impact from Coupling Noise in Diagonal Bitline Architectures,” (U.S. patent application Ser. No. 09/406,892, Attorney Docket No. 99P07821US) which is herein incorporated by reference for all purposes.

FIG. 4 shows a memory array 401 with diagonal bitlines. Illustratively, the memory array includes first and second banks 410a and 410b, each with a memory block 330a and 330b. The memory blocks are associated with respective wordline drivers 140a or 140b. As discussed, the first and second banks are mirrored images of each other. By providing first and second banks which are mirror images of each other, the direction of the bitlines in the adjacent blocks are reversed or switched. This creates large triangular open areas 495, which are unused between the memory blocks, undesirably increasing the array size.

As evident from the foregoing discussion, it is desirable to provide an IC having a memory array with diagonal bitlines, which makes more efficient use of space and reduces the unused area created by directional changes of the bitlines, without following the conventional mirrored sub-array architecture.

### SUMMARY OF THE INVENTION

The invention relates generally to integrated circuits and more particularly to integrated circuits with memory arrays having diagonal bitlines. The memory array includes first and second adjacent memory banks. A memory bank includes a memory block associated with a driver. The memory block comprises a plurality of memory cells interconnected by wordlines and bitlines which are diagonal with respect to the wordlines. The memory block includes twists regions which changes the direction of the diagonal bitlines, creating zigzagged sides along the general direction of the bitlines.

The memory blocks of the banks are located adjacent to each other along the general direction of the bitlines, with the wordline drivers located on non-adjacent sides of the memory block along the general direction of the bitlines. In accordance with the invention, the diagonal bitlines are arranged to run along the same direction, which makes more efficient use of space on the IC and reduces the unused area created by zigzagged sides of the memory block.

### BRIEF DESCRIPTION OF THE DRAWINGS

FIG. 1 shows a conventional memory array with a mirrored sub-array (bank) architecture;

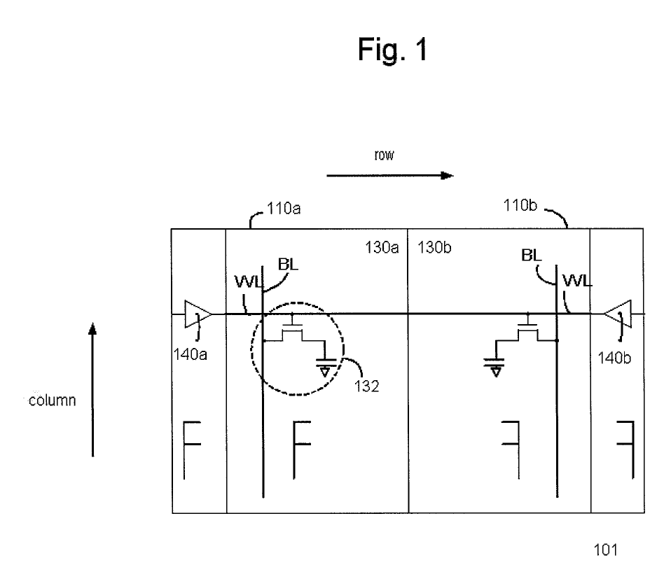

FIG. 2 shows a multi-level bitline architecture with vertical twists;

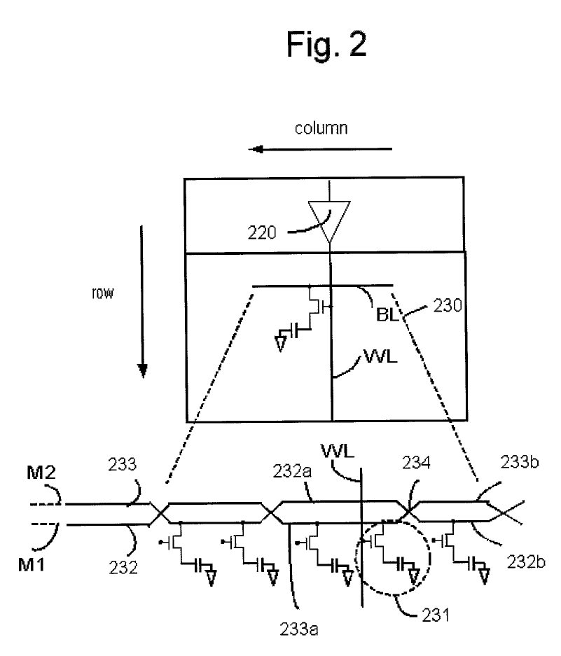

FIG. 3 shows a memory block implemented with multilevel bitlines having vertical twists;

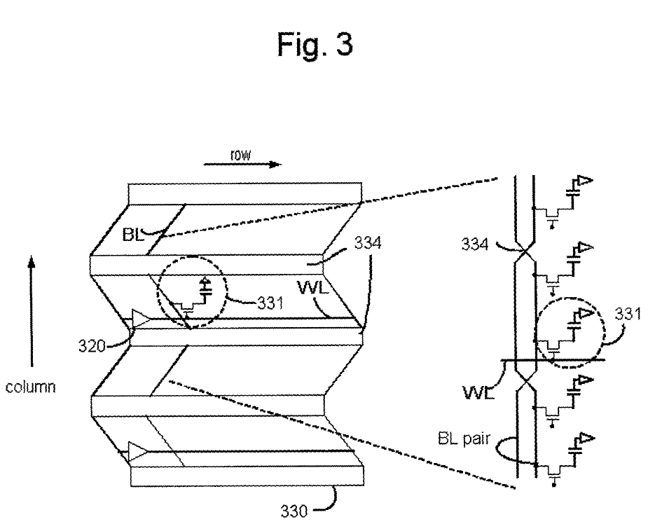

FIG. 4 shows a memory array with multi-level bitlines having vertical twists; and

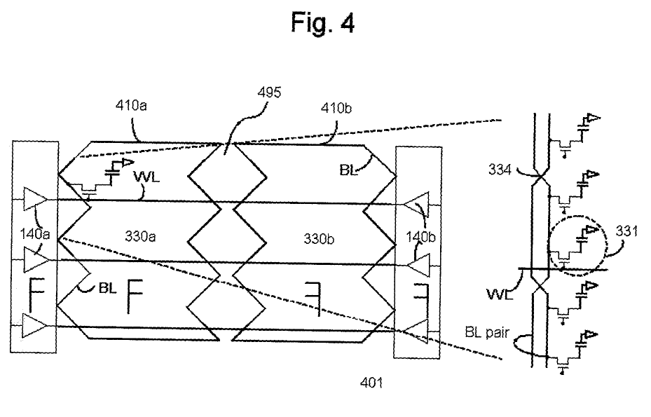

FIG. 5 shows a memory array with twisted bitlines in accordance with one embodiment of the invention.

### DESCRIPTION OF THE INVENTION

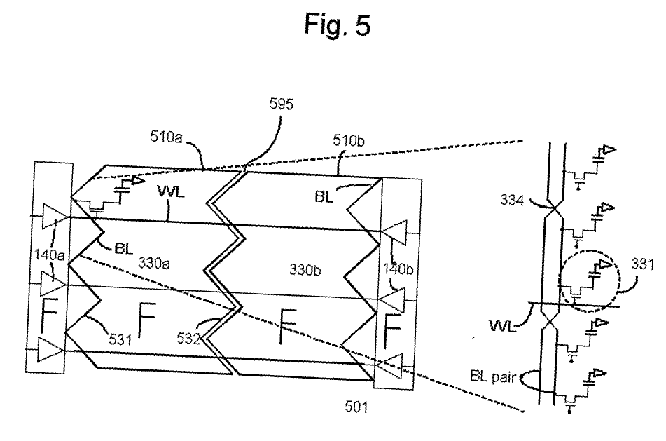

FIG. 5 shows a memory array 501 of an IC in accordance with one embodiment of the invention. The IC, for example, is a memory IC. Other types of ICs, such as logic or embedded ICs, are also useful. As shown, the memory array 501 includes first and second memory banks 510a and 510b. Each memory bank (510a or 510b) contains a memory block (330a or 330b). The memory blocks 330a and 330b contain a plurality of memory cells. The memory cells in each memory block are arranged in a matrix, and supported by wordlines (WLs) and bitlines (BLs). Although the invention is described with first and second banks, additional banks may be provided. The first memory bank 510a includes wordline drivers 140a associated with a memory block 330a. The first memory block 330a includes diagonal bitlines with directional changes, causing the first side 531 and second side 532 of the memory block along the direction of the bitlines to be jagged. As previously discussed in the background of the specification, the diagonal bitline arrangement is preferably used to implement a multi-level bitline architecture for the gigabyte generation and beyond. However, the invention is not limited to this configuration.

The second memory bank 510b includes wordline drivers 140b and a memory block 330b having diagonal bitlines. In accordance with the invention, the second bank is configured in the same manner or direction as the first bank (i.e. not flipped or mirrored). Wordline drivers 140b are located on the side of the memory block opposite the side adjacent to the first bank, similar to the conventional mirrored sub-array architecture. By arranging the memory blocks of the first and second banks in the same direction, the bitlines of the adjacent blocks run in the same direction. As a result, the jagged sides of adjacent memory blocks coincide with each other, thereby reducing the wasted space 595 between adjacent memory blocks.

While the invention has been particularly shown, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

What is claimed is:

1. An integrated circuit having a memory array comprising:
first and second adjacent memory banks, wherein the memory banks include respective memory blocks which are adjacent and having diagonal bitlines; and
first and second wordline drivers associated with respective first and second memory blocks, the wordline drivers located on non-adjacent sides of the memory blocks along the general direction of the bitlines;
wherein the bitlines of the first and second banks run in a same direction to reduce unused space created by the zigzagged sides of the memory blocks.

2. The integrated circuit of claim 1 wherein the integrated circuit comprises a memory integrated circuit.

3. The integrated circuit of claim 2 wherein the array comprises multi-level bitline architecture with vertical twists in twist regions to switch bitlines of a bitline pair from a first level to a second level.

4. The integrated circuit of claim 3 wherein the first level is below the second level.

5. The integrated circuit of claim 3 comprises memory cells coupled to segments of bitlines of the bitline pair located on a first level.

6. The integrated circuit of claim 5 wherein the first level is below the second level.

7. The integrated circuit of claim 1 wherein the array comprises multi-level bitline architecture with vertical twists in twist regions to switch bitlines of a bitline pair from a first level to a second level.

8. The integrated circuit of claim 7 wherein the first level is below the second level.

9. The integrated circuit of claim 7 comprises memory cells coupled to segments of bitlines of the bitline pair located on a first level.

10. The integrated circuit of claim 9 wherein the first level is below the second level.
